(19) United States
(12) Patent Application Publication
(10) Pub. No.: US 2002/0127486 A1
(43) Pub. Date: Sep. 12, 2002

(54) Shot configuration measuring mark and transfer error detection method using the same

(75) Inventor: Hirofumi Saito, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/090,883

(22) Filed: Mar. 5, 2002

(30) Foreign Application Priority Data
Mar. 12, 2001 (JP) 68293/2001

(51) Int. Cl. G03F 9/00; G03C 5/00; H01L 23/544

(52) U.S. Cl. 430/30; 438/975; 257/797; 430/22

(57) ABSTRACT

A shot configuration measuring mark transferred onto a resist film formed on a semiconductor wafer includes four straight-line marks arranged in parallel to each other and a centerline between outer two of the four straight-line marks is coincident with a centerline between inner two of the four straight-line marks.

### BACKGROUND OF THE INVENTION

1. Field of the-Invention

The present invention relates to a shot configuration measuring mark suitable for a pattern formation on a semiconductor wafer and -a transfer error detection method using the same mark and, in particular, a shot configuration measuring mark for use in enlarging a maximum exposure area of a reduction projection exposing device and a transfer error detection method using the same mark.

2. Description of the Prior Art

It has been required, in forming a pattern on a semiconductor wafer, to precisely measure a shot configuration, that is, the pattern transferred onto the semiconductor wafer by a reduction projection exposing device and feed back a measured value to the reduction projection exposing device, even in a case where there is no mark for measuring the shot configuration in such a case where a first exposure is performed on a semiconductor wafer. Therefore, correctness of a shot configuration has been managed by daily check of the reduction projection-exposing device. In such managing method, however, it is impossible to maintain a shot configuration of a semiconductor product completely correctly even if the shot configuration is regulated by such daily check since there may be a case where an original pattern, that is, a reticle, used in the daily check is different from a reticle of a semiconductor product or the daily check is made at a time different from a time of an exposing step of the semiconductor product.

Japanese Patent Application Laid-open No. H10-274855 (JP 10-274855 A) discloses a method for evaluating correctness of a shot configuration even when there is no underlying pattern. In the disclosed method, a couple of measuring marks are formed in peripheral portions of a rectangular chip forming region of a semiconductor wafer and an overlapping condition of the measuring marks is investigated after a couple of exposures are performed. In more detail, two square measuring marks are formed in an outer area of each of two adjacent sides of the rectangular area and two square measuring marks, which are smaller than the former measuring marks, are formed in an outer area of each of two adjacent sides opposing to the former two adjacent sides. These measuring marks are designed in such a way that centers of these measuring marks in the pattern transferred in a shot become coincident with those transferred in a next shot. Therefore, it is possible to detect a transfer error by measuring deviations between the centers after the transferring steps are completed.

However, since the configuration of the measuring mark used in a conventional overlapping measuring: device is a square having each side as long as 40 μm, there is a problem that it is necessary to make an overlapping portion of two shots sufficiently large. However, when the overlapping portion is set large, the maximum exposure region of the reduction projection-exposing device is narrowed.

### SUMMARY OF THE INVENTION

The present invention was made in view of such problem and has an object to provide a shot configuration measuring mark, which is capable of narrowing an overlapping portion of a first shot and a second shot on a semiconductor wafer in measuring a deviation between the two shots and a transfer error detection method using the same shot configuration measuring mark.

The shot configuration measuring mark according to the present invention, which is transferred onto a resist film formed on a semiconductor, is featured by including four marks, which have straight-line configurations and are arranged in parallel to each other, a centerline between outer two of the four marks being coincident with a centerline between inner two of the four marks.

In the present invention, if there is errors due to transferring magnification error, rotation error or distortion error, that is, skew error, in the centerline between the outer two straight-line marks and the centerline between the inner two straight-line marks are not coincident with each other. Therefore, it is possible to determine correctness of the shot configuration by detecting an overlapping of the two centerlines. On the other hand, if the centerlines are not overlapped and the shot is to be corrected, it is possible to precisely form a new transfer pattern easily by feeding back a deviation between the two centerlines. Further, since it is enough to provide four straight-line marks as the shot configuration measuring mark, width of the overlapped portion of two patterns transferred in different exposing steps can be made small enough. For example, the correctness of the shot configuration can be determined by the overlapped portion having a width in a range from 1 μm to 2 μm. Therefore, it becomes possible to effectively use an area capable of being exposed by a reduction projection exposing device.

Incidentally, it is preferable that three of the four straight-line marks are formed simultaneously with a transfer of a reticle in a first chip forming area of the semiconductor wafer and the remaining straight-line mark is formed simultaneously with a transfer of a reticle in a second chip forming area, which is adjacent to the first chip forming area of the semiconductor wafer.

Furthermore, at least one of the four straight-line marks is preferably formed in an area in which the transfers of the reticles in the first and second chip forming areas are overlapped.

The transfer error detection method according to the present invention is featured by comprising the steps of transferring three straight-line marks arranged in parallel to each other onto a resist film formed on a semiconductor wafer simultaneously with a transfer of a reticle in a first chip forming area of the semiconductor wafer and transferring one straight-line mark arranged in parallel to the three straight-line marks onto the resist film simultaneously with a transfer of a reticle in a second chip forming area, which is adjacent to the first chip forming area of the semiconductor wafer, in such a way that a centerline between outer two of the four straight-line marks is coincident with a centerline between inner two of the four straight-line marks.

Moreover, at least one of the four straight-line marks is preferably formed in an area in which the transfers of reticles in the first and second chip forming areas are overlapped.

Furthermore, it is possible to determine the coincidence of the two centerlines by detecting positions of the four straight-line marks.

### BRIEF DESCRIPTION OF THE DRAWINGS

FIG. 1 is a plan view of a shot configuration measuring mark according to a first embodiment of the present invention;

FIG. 2A is a plan view showing an error detection method using the shot configuration-measuring mask shown in FIG. 1 in a case there is no transferring magnification error;

FIG. 2B is a plan view showing an error detection method using the shot configuration-measuring mask shown in FIG. 1 in a case where transferring magnification error becomes small;

FIG. 3 is a plan view of a shot configuration measuring mark according to a second embodiment of the present invention;

FIG. 4A is a plan view showing an error detection method for detecting an error caused by rotation of the shot configuration by using the shot configuration measuring mask shown in FIG. 3 in a case there is no rotation;

FIG. 4B is a plan view showing an error detection method for detecting an error caused by rotation of the shot configuration by using the shot configuration measuring mask shown in FIG. 3 in a case where there is clockwise rotation;

FIG. 5 is a plan view of a shot configuration measuring mark according to a third embodiment of the present invention; and

FIG. 6 is a plan view of a shot configuration measuring mark according to a fourth embodiment of the present invention;

### DETAILED DESCRIPTION OF THE PREFERRED EMBODIMENTS

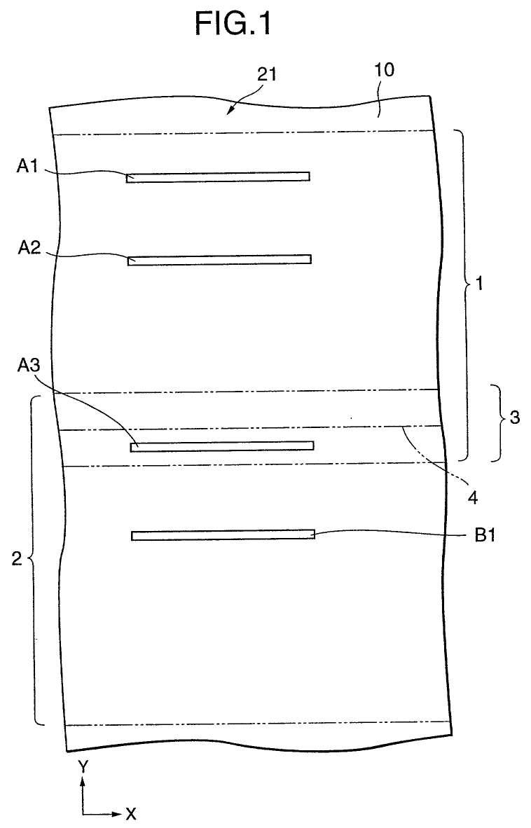

As shown in FIG. 1, a first embodiment of the present invention is a shot configuration measuring mark, which is inserted into scribing line regions and used to measure an error of transferring magnification in a direction (referred to as Y direction, hereinafter) of a surface of a semiconductor wafer. The scribing line regions extend in a direction (referred to as X direction, hereinafter) perpendicular to the Y direction and scribing lines are provided in the scribing line regions.

The shot configuration measuring mark 21 according to the first embodiment is constituted with four straight-line marks A1, A2, A3 and B1. A resist film 10 is formed on the semiconductor wafer and the straight-line marks Al, A2, A3 and B1 arranged in the order in Y direction are formed on the resist film 10 by two shots. The straight-line marks A1, A2 and A3 are transferred in a first shot (first exposure step) and only the straight-line mark B1 is transferred in a second shot (second exposure step). The straight-line marks A1, A2 and A3 are formed in a scribing line region 1 of a pattern formed by the first shot and the straight-line mark B1 is formed in a scribing line region 2 of a pattern formed by the second shot.

The scribing line regions 1 and 2 are partially overlapped and the straight-line mark A3, for example, is formed within an overlapped portion 3 of the scribing line regions 1 and 2. A centerline of the overlapped portion 3, which extends in X direction becomes a scribing line center 4. The straight-line marks A1, A2, A3 and B1 are, for example, about 10 μm long, a distance between the straight-line mark A1 and the straight-line mark B1 is, for example, about 20 μm and a distance between the straight-line mark A2 and the straight-line mark A3 is, for example, about 10 μm. These numerical values are selected in such a way that the straight-line marks A1, A2, A3 and B1 come in sight of an overlapping accuracy measuring device for measuring positions of these straight-line marks.

The straight-line marks A1, A2, A3 and B1 can be formed by forming a transparent region for forming the straight-line marks A1, A2 and A3 in the scribing line region in one end portion of a reticle in Y direction, forming a transparent region for forming the straight-line mark B1 in the scribing line region in the other end portion and exposing the resist film 10 by a reduction projection exposing device, etc., by using this reticle. In this case, the reticle is designed in such a way that the centerline between the straight-line marks A1 and B1 becomes coincident with the centerline between the straight-line marks A1 and B1.

Incidentally, when the resist film 10 is of positive type, the straight-line marks A1, A2, A3 and B1 are removed by subsequent developing step and, when the resist film 10 is of negative type, these straight-line marks are left as they are in the subsequent developing step.

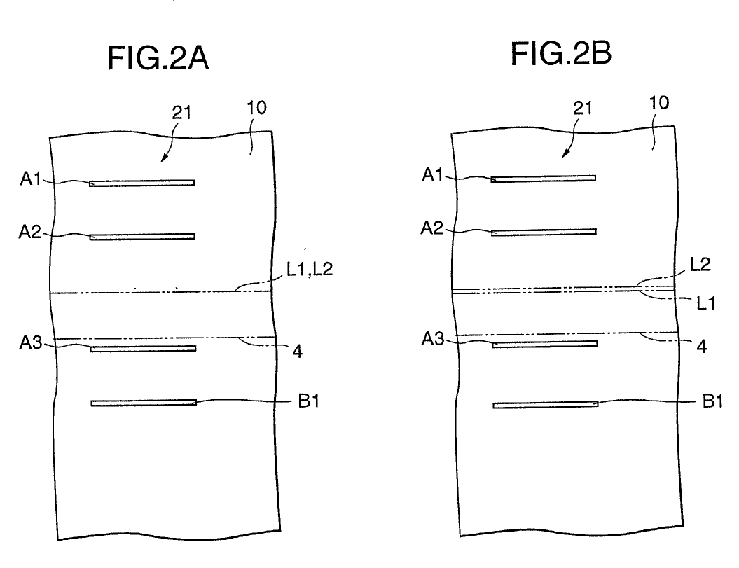

Now, a transferring magnification error detection method using the shot configuration measuring mark constructed as mentioned above will be described with reference to FIG. 2A, which shows a case where there is a transferring magnification error and FIG. 2B, which shows a case where the transferring magnification error becomes small.

As described previously, the shot configuration measuring mark is designed in such a way that the centerline between the straight-line mark A1 and the straight-line mark B1 is coincident with the centerline between the straight-line mark A2 and the straight-line mark A3. Therefore, if there no error in transferring magnification, the centerline L1 between the straight-line mark A1-and the straight-line mark B1 is overlapped with the centerline L2 between the straight-line mark A2 and the straight-line mark A3, as shown in FIG. 2A.

On the other hand, if transferring magnification becomes small, the straight-line marks A1, A2 and A3 are moved to a center of a pattern formed by a first shot and the straight-line mark B1 is moved to a center of a pattern formed by a second shot. As a result, the centerline L1 is moved from the centerline L2 to a position on the side of straight-line mark B1, as shown in FIG. 2B. On the contrary, if the transferring magnification becomes large, centerline L2 is moved from the centerline L1 to a position on the side of straight-line mark B1.

Therefore, after the development is finished, magnitude of error, if any, can be known by detecting positions of the straight-line marks A1, A2, A3 and B1 by an overlapping measuring device, etc., which can detect positions of the straight-line marks in at least one direction, and obtaining a positional relation between the centerlines L1 and L2 on the basis of the detected positions.

Thereafter, if it is determined that the distance between the centerlines L1 and L2 is so large that succeeding semiconductor producing steps are influenced adversely, the resist film 10 is peeled off and exposure and then development are performed by feeding back the detected positions of the straight-line marks A1, A2, A3 and B1 to the reduction projection exposing device. The feedback of the detected positions may be done by substituting the detected values for the offset values of the shot configuration of the reduction projection-exposing device, for example. On the other hand, in a case where the centerlines L1 and L2 are coincident or the distance therebetween is sufficiently small, the succeeding steps may be performed successively as usual.

When a distance between two marks formed in different shots is to be measured, the distance corresponds to a deviation produced in two shots, namely, twice a deviation in one shot. In this embodiment, however, there is no need of dividing the measured value by 2 since only the straight-line mark B1 of the four straight-line marks is formed in the second shot.

Incidentally, although the first embodiment is the straight-line marks for measuring the transferring magnification in the Y direction, it is possible to measure a transferring magnification in the X direction by rotating the straight-line marks by 90° and inserting them into the scribing line region extending in the Y direction.

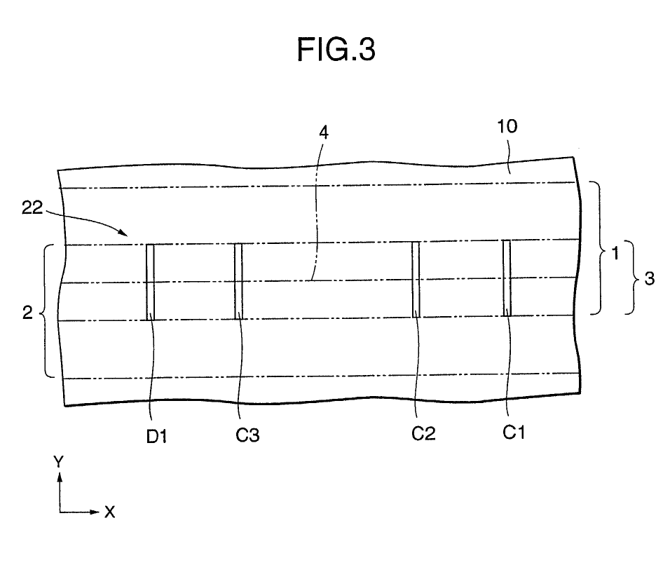

Now, a second embodiment of the present invention will be described with reference to FIG. 3. The second embodiment resides in straight-line marks, which are inserted into the scribing line region extending the X direction on a semiconductor wafer surface and used in measurement of error, which is caused by rotation of reticles in-a transferring operation.

A shot configuration measuring mark 22 according to the second embodiment is constructed with four straight-line marks C1, C2, C3 and D1. A resist film 10 is formed on the semiconductor wafer and the straight-line marks C1, C2, C3 and D1 are formed on the resist film 10 in this sequence in the X direction by two shots. The straight-line marks C1, C2 and C3 are formed by a first shot and the straight-line mark D1 is formed by a second shot. The straight-line marks C1, C2 and C3 are formed in a scribing line region 1 of a pattern of the first shot and the straight-line mark D1 is formed in a scribing line region 2 of a pattern of the second shot.

In the second embodiment, the straight-line marks C1, C2, C3 and D1 are formed in an overlapped portion 3 of the scribing line regions 1 and 2. The straight-line marks C1, C2, C3 and D1 are, for example, about 5-10 μm long, a distance between the straight-line mark C1 and the straight-line mark D1 is, for example, about 20 μm and a distance between the straight-line mark C2 and the straight-line mark C3 is, for example, about 10 μm. These numerical values are selected in such a way that the straight-line marks C1, C2, C3 and D1 come in sight of an overlapping accuracy measuring device for measuring positions of these straight-line marks. Incidentally, centers of the straight-line marks C1, C2, C3 and D1 in longitudinal direction is positioned on a center 4 of the scribing line region.

The straight-line marks C1, C2, C3 and D1 can be formed by forming a transparent region for forming the straight-line marks C1, C2 and C3 in the scribing line region in one end portion of a reticle in the X direction, forming a transparent region for forming the straight-line mark Dl in the scribing line region in the other end portion and exposing the resist film 10 by a reduction projection exposing device, etc., by using this reticle. In this case, the reticle is designed in such a way that the centerline between the straight-line marks C1 and D1 becomes coincident with the centerline between the straight-line marks C2 and C3.

Incidentally, when the resist film 10 is of positive type, the straight-line marks C1, C2, C3 and D1 are removed by subsequent development and, when the resist film 10 is of negative type, these straight-line marks are left as they are in the subsequent development.

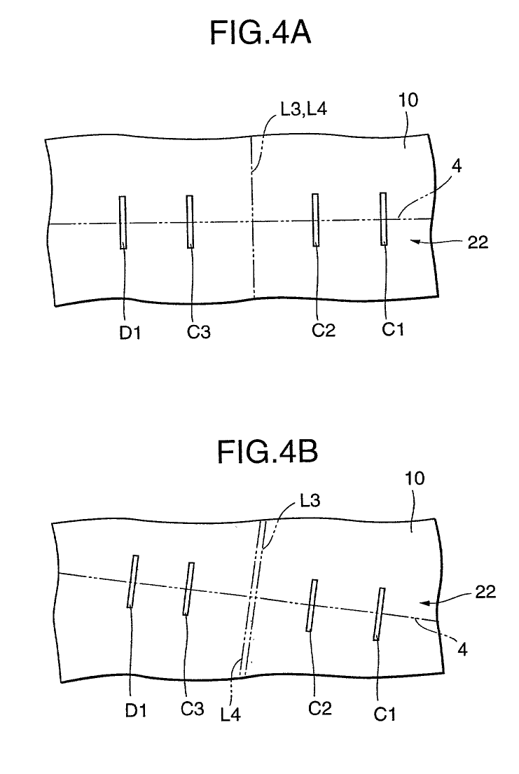

Now, a rotation error detection method using the shot configuration measuring mark constructed according to the second embodiment will be described with reference to FIG. 4A and FIG. 4B, which show a case where there is no rotation error and a case where a clockwise rotation exists, respectively.

As described previously, the shot configuration measuring mark is designed in such a way that the centerline between the straight-line mark C1 and the straight-line mark D1 is coincident with the centerline between the straight-line mark C2 and the straight-line mark C3. Therefore, if there is no rotation error, the centerline L3 between the straight-line mark C1 and the straight-line mark D1 is overlapped with the centerline L4 between the straight-line mark C2 and the straight-line mark C3, as shown in FIG. 4A. On the other hand, if the clockwise rotation occurs, the centerline L4 is moved from the centerline L3 to a position on the side of the straight-line mark D1 as shown in FIG. 4B. On the contrary, if counterclockwise rotation occurs, the centerline L3 is moved from the centerline L4 to a position on the side of the straight-line mark D1 as shown in FIG. 4B.

Therefore, after the development is finished, rotation error, if any, and its magnitude can be known by detecting positions of the straight-line marks C1, C2, C3 and D1 by the overlapping measuring device, etc., which can detect position in at least one direction, and obtaining a positional relation between the centerlines L3 and L4 on the basis of the detected positions.

Incidentally, although the second embodiment is the straight-line marks for measuring the rotation error by using the scribing line region extending in the X direction as the reference, it is possible to measure an error of rotation from the scribing line region extending in the Y direction by rotating the marks by 90° and inserting them into the scribing line region extending in the Y direction. In a case where only the transferring magnification error and the rotation error occur, the rotation errors from the two scribing line regions extending in the X and Y directions, respectively, are the same. However, when there is a distortion (skew) in addition to the transferring magnification error and the rotation error, these errors are not coincident. In such case, a total error R can be obtained by the following equation 1:

R=(RX+RY)/2 (1)

where RX is the error with respect to the scribing line region extending in the X direction as the reference and RY is the error with respect to the scribing line region extending in the Y direction as the reference.

That is, it is possible to obtain the total error as an average of the errors measured by using the respective scribing line regions as the references.

A magnitude of the distortion, that is, skew S, is obtained by the following equation 2:

S=(RX−RY)/2 (2)

Thereafter, when the total error R or the skew S is determined as so large that the subsequent production steps are influenced adversely, the resist film 10 is peeled off and then exposure and development are performed by feeding back the detection result to the reduction projection exposing device.

The feedback may be done by substituting the detected values for the offset values of the shot configuration of the reduction projection-exposing device, for example. On the other hand, in a case where the centerlines L3 and L4 are coincident or the distance therebetween is sufficiently small, the succeeding steps may be performed successively as usual.

When a distance between two marks formed in different shots is to be measured, the distance corresponds to a deviation in two shots, namely, twice the deviation in one shot. In this embodiment, there is no need of dividing the measured value by 2 since only the straight-line mark D1 of the four straight-line marks is formed in the second shot.

Incidentally, although, in the first and second embodiments, the respective straight-line marks are formed within the scribing line regions, the straight-line marks may be formed in chip forming regions of the scribing line regions.

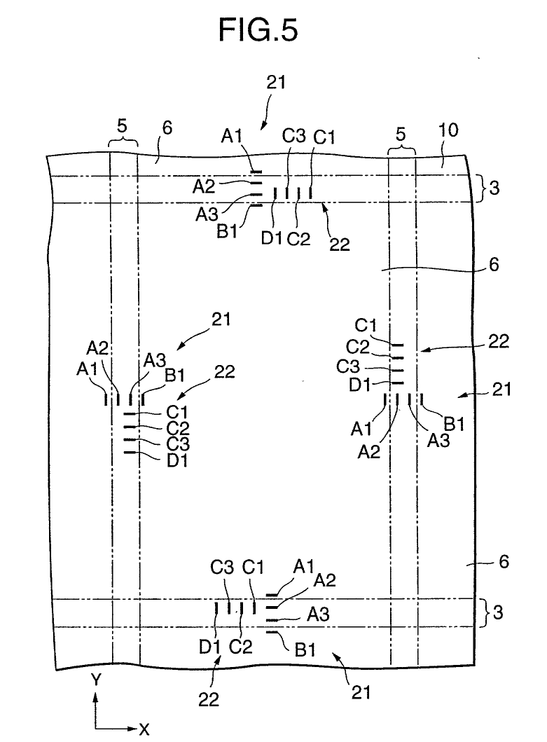

Now, a third embodiment of the present invention, which is a combination of the first and second embodiments, will be described with reference to FIG. 5.

In the third embodiment, a shot configuration measuring mark 21 of the first embodiment and a shot configuration measuring mark 22 of the second embodiment are formed in each of scribing line regions 3 between two chip forming regions 6 adjacent to each other in the Y direction and extending in the X direction. Similarly, a shot configuration measuring mark 21 of the first embodiment and a shot configuration measuring mark 22 of the second embodiment are formed in each of scribing line regions 5 between two chip forming regions 6 adjacent to each other in the X direction and extending in the Y direction. It should be noted that the shot configuration measuring marks 21 and 22 formed in the scribing line region 5 are obtained by rotating those shown in FIG. 1 and FIG. 3 by 90° , respectively.

According to the third embodiment, it is possible to simultaneously measure the transferring magnification errors in the X and Y directions, the error due to rotation and the error due to distortion.

By forming the two shot configuration measuring marks 22 according to the second embodiment in the scribing line regions between the two chip regions, it becomes possible to measure the transferring magnification errors in the X and Y directions similarly to the shot configuration measuring mark 21 of the first embodiment.

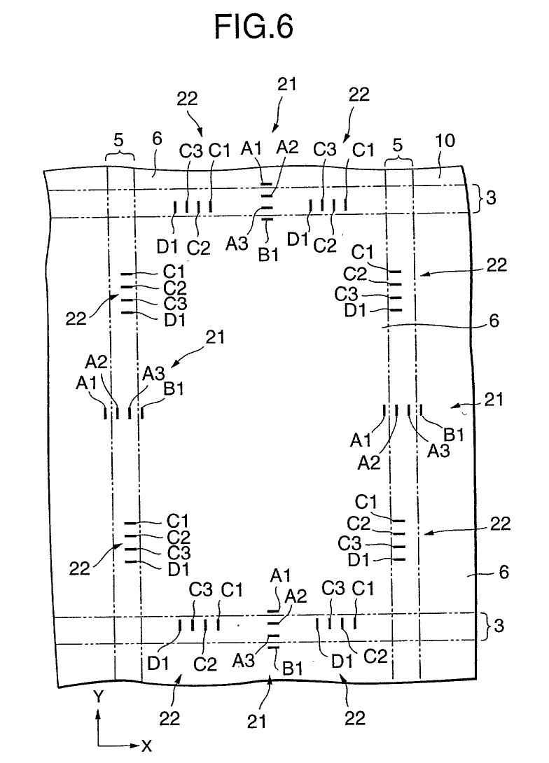

Now, a fourth embodiment of the present invention will be described with reference to FIG. 6. In the fourth embodiment, two shot configuration measuring marks 22 are formed within each of scribing line regions 5 extending in the Y direction.

According to the fourth embodiment, it is possible to measure an error more precisely by averaging the measured values by the two shot configuration-measuring marks 22.

The number of shot configuration measuring marks formed within each scribing line region formed between two chip forming regions is not specifically limited. However, since the shot configuration measuring mark according to the present invention is formed by overlapping of two shots, it is influenced by preciseness of the shot arrangement. Therefore, a more precise measurement becomes possible by forming a plurality of shot configuration measuring marks and averaging measured values measured by using these shot configuration measuring marks. It is preferable to form one or more shot configuration measuring marks for measuring the transferring magnification error in one scribing line region and it is preferable to form two or more shot configuration measuring marks for measuring the rotation and distortion errors in one scribing line region.

Furthermore, although, in the first to fourth embodiments, outside one of the fourth straight-line marks is transferred in an exposing step different from the exposing step in which the rem aining three straight-line marks are transferred, it may be possible to transfer inner one of the fourth straight-line marks is transferred in an exposing step different from the exposing step in which the remaining three straight-line marks are transferred.

As described in detail hereinafter, according to the present invention, it is possible to determine the correctness of the shot configuration by detecting the overlapping of the two centerlines. Further, when the centerlines are not overlapped and a correction is necessary, it is possible to easily form a new transfer pattern precisely by merely feeding back an amount of deviation between the two centerlines. Moreover, since four straight-line marks are provided for measurement of the shot configuration, it is possible to effectively use an area covered by the reduction projection-exposing device even when the width of the overlapped portion due to two transfers is small.

What is claimed is:

1. A shot configuration measuring mark comprising:
four straight-line marks arranged in parallel to each other and transferred onto a resist film formed on a semiconductor wafer, a centerline between outer two of said four straight-line marks being coincident with a centerline between inner two of the four straight-line marks.

2. A shot configuration measuring mark as claimed in claim 1, wherein three of said four straight-line marks are formed simultaneously with a transfer in a first chip forming area in said semiconductor wafer and the remaining one of said four straight-line marks is formed simultaneously with a transfer in a second chip forming area adjacent to said first chip forming area of said semiconductor wafer.

3. A shot configuration measuring mark as claimed in claim 2, wherein at least one of said four straight-line marks is formed in a region in which said transfers in said first and second chip forming regions are overlapped.

4. A transfer error detection method comprising the steps of:
transferring three straight-line marks arranged in parallel to each other onto a resist film formed on a semiconductor wafer simultaneously with a transfer in a first chip forming area in said semiconductor wafer; and
transferring a straight-line mark arranged in parallel to said three straight-line marks onto said resist film simultaneously with a transfer in a second chip forming area of said semiconductor wafer adjacent to said first chip forming area in such a way that a centerline between outer two of said four straight-line marks is coincident with a centerline between inner two of said four straight-line marks.

5. A transfer error detection method as claimed in claim 4, wherein at least one of said four straight-line marks is formed in a region in which said transfers in said first and second chip forming regions are overlapped.

6. A transfer error detection method as claimed in claim 4, further comprising the step of determining a coincidence of said two centerlines by detecting positions of said four straight-line marks.
